(19) United States
(12) Patent Application Publication
(10) Pub. No.: US 2026/0011643 A1
(43) Pub. Date: Jan. 8, 2026

(54) OUTPUT CIRCUIT

(71) Applicant: Socionext Inc., Kanagawa (JP)

(72) Inventor: Isaya SOBUE, Yokohama-shi, Kanagawa (JP)

(21) Appl. No.: 19/326,227

(22) Filed: Sep. 11, 2025

Related U.S. Application Data
(63) Continuation of application No. PCT/JP2024/012187, filed on Mar. 27, 2024.

(30) Foreign Application Priority Data
Apr. 5, 2023 (JP) 2023-061427

(51) Int. Cl. H01L 23/528; H01L 23/498; H01L 23/522; H10D 84/85

(52) U.S. Cl. CPC H01L 23/5286; H01L 23/5226; H01L 23/5283; H01L 23/49827; H01L 23/49838; H10D 84/851

(57) ABSTRACT

In an output circuit of a semiconductor integrated circuit device, an output transistor part including a transistor connected between VSS and an output terminal has first and second active regions overlapping each other in planar view. A power line and an output line are placed in an interconnect layer on the back side so as to overlap the first and second active regions in planar view. The power line is connected to the lower face of the portion that is to be the source of the first active region through a via, and the output line is connected to the lower face of the portion that is to be the drain of the first active region through a via.

### CROSS-REFERENCE TO RELATED APPLICATIONS

This is a continuation of International Application No. PCT/JP2024/012187 filed on March 27, 2024, which claims priority to Japanese Patent Application No. 2023-061427 filed on April 5, 2023. The entire disclosures of these applications are incorporated by reference herein.

### BACKGROUND

The present disclosure relates to a semiconductor integrated circuit device, and more particularly to a layout structure of an output circuit.

A semiconductor integrated circuit device includes an input/output circuit that performs input/output of signals from/to the outside via input/output pads. As for an output circuit in the input/output circuit, which passes a large current, full attention must be paid to its layout structure.

US Patent Application Publication No. 2022/0123023 (FIG. 2A) proposes, for higher integration of a semiconductor integrated circuit device, a configuration in which transistors are stacked one upon another and moreover interconnects are laid right under the transistors.

The cited patent document however does not disclose a specific layout structure about a circuit that passes a large current, like an output circuit in an input/output circuit, in the configuration in which transistors are stacked one upon another and moreover interconnects are laid right under the transistors.

An objective of the present disclosure is presenting an output circuit capable of passing a large current to an output terminal in a semiconductor integrated circuit device having a configuration in which transistors are stacked one upon another and moreover interconnects are laid right under the transistors.

### SUMMARY

According to the first mode of the disclosure, an output circuit for outputting a signal from a semiconductor integrated circuit includes: a first output transistor part including a first transistor of a first conductivity type connected between a first power supply supplying a first power supply voltage and an output terminal; a first power line supplying the first power supply voltage; and an output line connected to the output terminal, wherein the first output transistor part includes a first active region forming a channel, source, and drain of the first transistor, and a second active region forming a channel, source, and drain of the first transistor, formed in a layer above the first active region, and overlapping the first active region in planar view, the first power line is placed on a back side of the first transistor so as to overlap the first and second active regions in planar view, and connected to a lower face of a portion that is to be the source of the first transistor in the first active region through a via, and the output line is placed in a same interconnect layer as the first power line so as to overlap the first and second active regions in planar view, and connected to a lower face of a portion that is to be the drain of the first transistor in the first active region through a via.

According to the above mode, in the output circuit, the first output transistor part including a first transistor connected between the first power supply and the output terminal has first and second active regions. The first and second active regions overlap each other in planar view, constituting the first transistor. A first power line and an output line are placed in an interconnect layer on the back side of the first transistor so as to overlap the first and second active regions in planar view. The first power line is connected to the lower face of the portion that is to be the source of the first transistor in the first active region through a via, and the output line is connected to the lower face of the portion that is to be the drain of the first transistor in the first active region through a via. With this configuration, an output circuit capable of passing a large current to the output terminal can be implemented without the need to widen the layout area.

According to the second mode of the disclosure, an output circuit for outputting a signal from a semiconductor integrated circuit includes: a first output transistor part including first and second transistors of a first conductivity type connected serially between a first power supply supplying a first power supply voltage and an output terminal; a first power line supplying the first power supply voltage; and an output line connected to the output terminal, wherein the first output transistor part includes a first active region, and a second active region formed in a layer above the first active region and overlapping the first active region in planar view, at least one of the first and second active regions forms channels, sources, and drains of the first and second transistors, the first power line is placed on a back side of the first and second transistors so as to overlap the first and second active regions in planar view, and connected to a lower face of a portion that is to be the source of the first transistor in the first active region through a via, and the output line is placed in a same interconnect layer as the first power line so as to overlap the first and second active regions in planar view, and connected to a lower face of a portion that is to be the drain of the second transistor in the first active region through a via.

According to the above mode, in the output circuit, the first output transistor part including first and second transistors connected serially between the first power supply and the output terminal has first and second active regions. The first and second active regions overlap each other in planar view, and at least one of the active regions constitutes the first and second transistors. A first power line and an output line are placed in an interconnect layer on the back side of the first and second transistors so as to overlap the first and second active regions in planar view. The first power line is connected to the lower face of the portion that is to be the source of the first transistor in the first active region through a via, and the output line is connected to the lower face of the portion that is to be the drain of the second transistor in the first active region through a via. With this configuration, an output circuit capable of passing a large current to the output terminal can be implemented without the need to widen the layout area.

According to the present disclosure, an output circuit capable of passing a large current to an output terminal can be implemented in a semiconductor integrated circuit device having a configuration in which transistors are stacked one upon another and moreover interconnects are laid right under the transistors.

### BRIEF DESCRIPTION OF THE DRAWINGS

FIG. 1 shows the entire configuration of a semiconductor integrated circuit device according to an embodiment.

FIG. 2 is a simplified configuration view of an IO cell.

FIG. 3 is a circuit diagram of an output circuit in the first embodiment.

FIG. 4 is a plan view showing a layout of the IO cell in the first embodiment.

FIG. 5 is a plan view showing the layout of the IO cell in the first embodiment.

FIG. 6 is a plan view showing the layout of the IO cell in the first embodiment.

FIG. 7A and FIG. 7B show cross-sectional structures of the layout of FIG. 4 to 6.

FIG. 8A shows another configuration example of the semiconductor integrated circuit device, and FIG. 8B shows a cross-sectional structure thereof.

FIG. 9 shows a cross-sectional structure of an alteration.

FIG. 10 is a circuit diagram of an output circuit in the second embodiment.

FIG. 11 is a plan view showing a layout of the IO cell in the second embodiment.

FIG. 12 is a plan view showing the layout of the IO cell in the second embodiment.

FIG. 13 is a plan view showing the layout of the IO cell in the second embodiment.

### DETAILED DESCRIPTION

Embodiments of the present disclosure will be described hereinafter with reference to the accompanying drawings. Note that, in the following description, "VSS" and "VDDIO" denote both the power supplies themselves and the power supply voltages. Also, "OUT" denotes both the output terminal and the output signal.

### (First Embodiment)

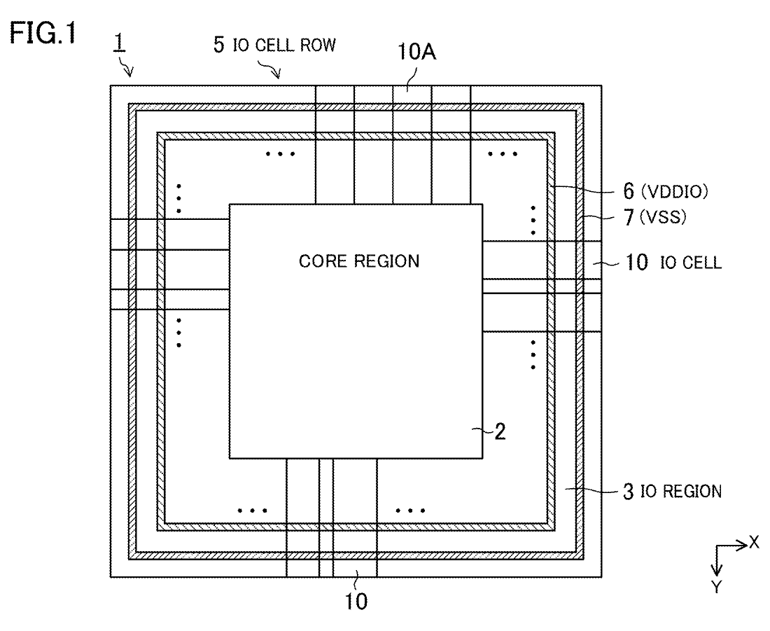

FIG. 1 is a plan view schematically showing the entire configuration of a semiconductor integrated circuit device (semiconductor chip) according to an embodiment. In FIG. 1, the horizontal direction in the figure is indicated as the X direction, and the vertical direction in the figure is indicated as the Y direction (this also applies to the figures to follow).

A semiconductor integrated circuit device 1 shown in FIG. 1 includes: a core region 2 in which inner core circuits are formed; and an IO region 3 provided around the core region 2, in which interface circuits (IO circuits) are formed. In the IO region 3, an IO cell row 5 is formed to surround the core region 2 in a peripheral portion of the semiconductor integrated circuit device 1. Although illustration is simplified in FIG. 1, a plurality of IO cells 10 constituting the interface circuits are arranged in the IO cell row 5.

The IO cells 10 include signal IO cells for performing input, output, or input/output of signals, power IO cells for supplying a ground potential (power supply voltage VSS), and power IO cells for supplying power (power supply voltage VDDIO) mainly to the IO region 3. VDDIO is 1.8 V, for example. In FIG. 1, an IO cell 10A for signal input/output is placed on the upper side of the core region 2 in the figure.

Power lines 6 and 7 extending in the direction in which the IO cells are arranged are provided in the IO region 3. The power lines 6 and 7 are each formed in a ring in the peripheral portion of the semiconductor integrated circuit device 1 (these power lines are also called the ring power lines). The power line 6 supplies VDDIO and the power line 7 supplies VSS. In this embodiment, the power lines 6 and 7 are formed in an interconnect layer located in the backside portion of a semiconductor chip in which transistors are formed. Although illustration is omitted in FIG. 1, a plurality of external connection pads are placed in the semiconductor integrated circuit device 1. In this embodiment, the plurality of external connection pads are placed on the back side of the semiconductor chip.

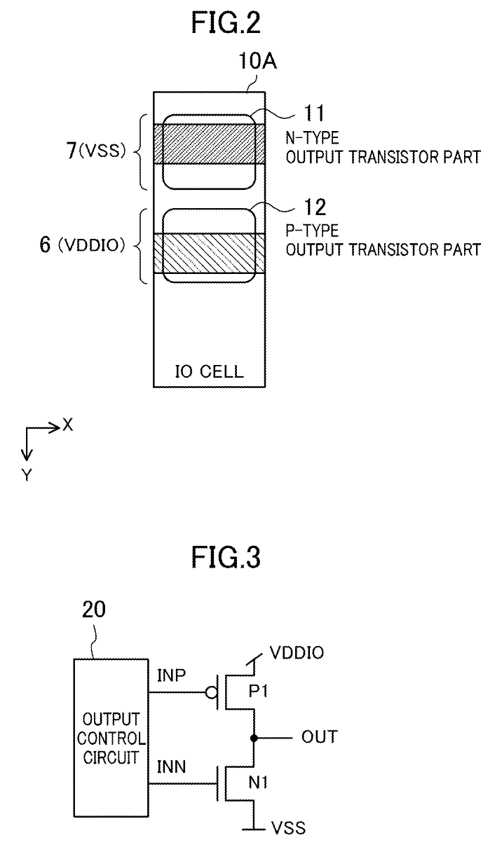

FIG. 2 is a simplified configuration diagram of the IO cell 10A. As shown in FIG. 2, the power lines 6 and 7 extending in the X direction are placed in the IO cell 10A. In the IO cell 10A, an n-type output transistor part 11 is provided above the power line 7, and a p-type output transistor part 12 is provided above the power line 6. The n-type output transistor part 11 and the p-type output transistor part 12 are provided at positions closer to the chip outer edge in the IO cell 10A.

FIG. 3 is a circuit diagram of an output circuit in this embodiment. In this embodiment, the IO cell 10A of FIG. 2 includes the output circuit shown in FIG. 3. In the output circuit of FIG. 3, a p-conductivity type (hereinafter called a p-type appropriately) transistor P1 is provided between the power supply VDDIO and an output terminal OUT (that outputs an output signal OUT), and an n-conductivity type (hereinafter called an n-type appropriately) transistor N1 is provided between the power supply VSS and the output terminal OUT. An output control circuit 20 outputs output control signals INP and INN. The transistor P1 receives the output control signal INP at its gate, and the transistor N1 receives the output control signal INN at its gate. The output signal OUT is supplied to an external connection pad. When the output control signals INP and INN are low in level, the output signal OUT is high (VDDIO), and when the output control signals INP and INN are high, the output signal OUT is low (VSS).

In this embodiment, the transistors constituting the output circuit are implemented by complementary field effect transistors (CFETs) having a structure of stacking transistors one upon the other. Also, an interconnect layer is provided on the back side of the CFETs.

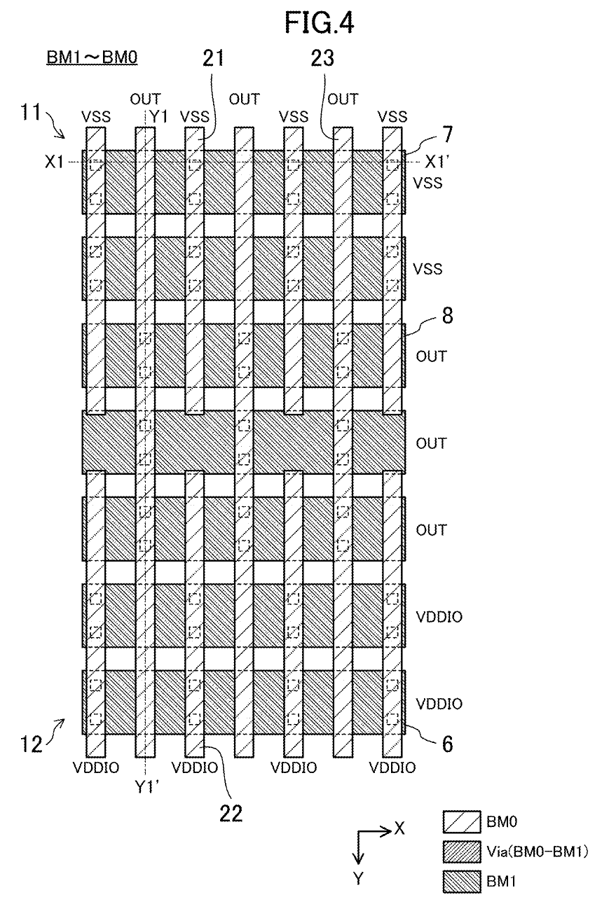

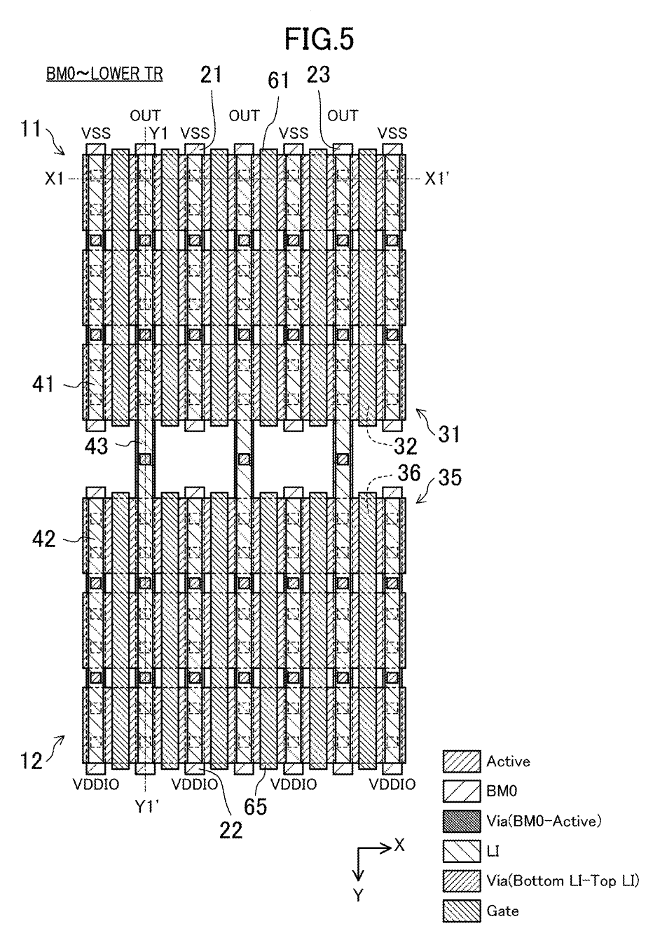

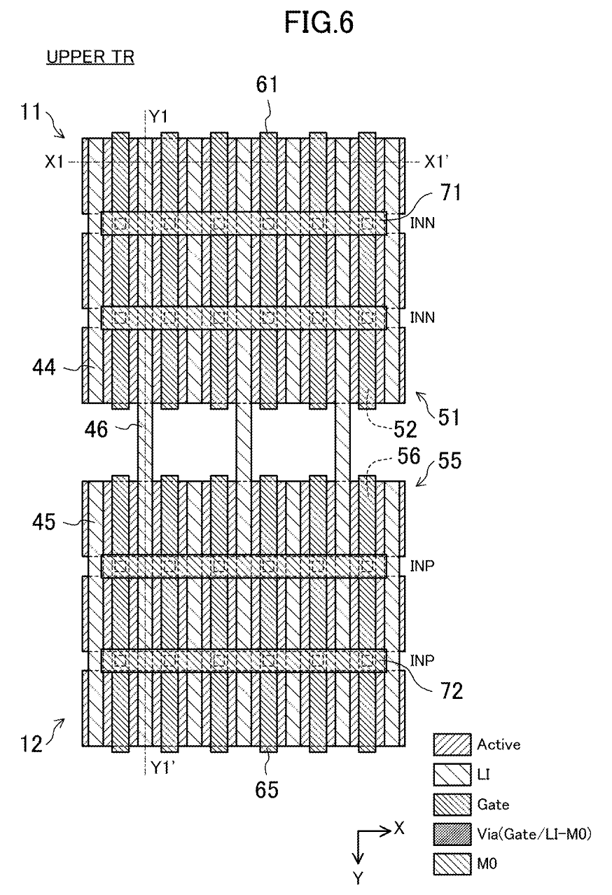

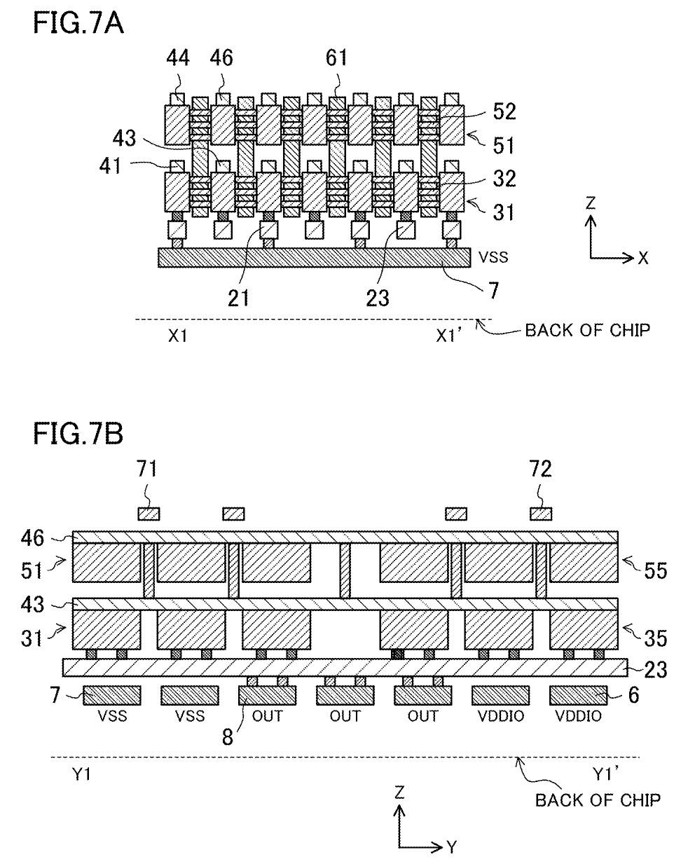

FIGS. 4, 5, and 6 are plan views showing a layout of the output transistor parts in the IO cell 10A shown in FIG. 2. FIGS. 4, 5, and 6 show the layout layer by layer: FIG. 4 shows a configuration of backside lines, FIG. 5 shows a configuration of a lower transistor (Tr.), and FIG. 6 shows a configuration of an upper transistor (Tr.). FIGS. 7A and 7B are cross-sectional views of the layout of FIGS. 4 to 6, where FIG. 7A shows a cross-sectional structure taken along line X1-X1' and FIG. 7B shows a cross-sectional structure taken along line Y1-Y1'. Note that the direction normal to the substrate plane is indicated as the Z direction.

In FIGS. 4 to 6, the upper part of the figure corresponds to the n-type output transistor part 11 constituting the transistor N1, and the lower part of the figure corresponds to the p-type output transistor part 12 constituting the transistor P1. Nanosheet field effect transistors (FETs) are formed in the n-type output transistor part 11 and the p-type output transistor part 12.

The n-type output transistor part 11 includes a lower active region 31 constituting the lower transistor and an upper active region 51 constituting the upper transistor. Similarly, the p-type output transistor part 12 includes a lower active region 35 constituting the lower transistor and an upper active region 55 constituting the upper transistor. The active region is a region forming the channel, source, and drain of a transistor. The active region constituting a nanosheet FET has a nanosheet as the channel. In the active region, portions that are to be the source and the drain on both sides of a nanosheet are formed by epitaxial growth from the nanosheet, for example.

A plurality of pad electrodes (not shown) are provided on the back of the semiconductor chip. The power supply voltages VDDIO and VSS are supplied from the outside of the semiconductor chip via the pad electrodes. Also, the output signal OUT is connected to the outside of the semiconductor chip via the pad electrodes.

A backside metal 0 (BMO) layer and a backside metal 1 (BM1) layer are provided as interconnect layers in the backside portion of the semiconductor chip in which the transistors are formed. The BM1 layer is located below the BMO layer, i.e., located farther from the transistors.

As shown in FIG. 4, in the BM1 layer, the power lines 6 and 7 shown in FIG. 2 are formed. The power lines 6 (two lines in FIG. 4) supplying VDDIO are provided under the p- type output transistor part 12, and the power lines 7 (two lines in FIG. 4) supplying VSS are provided under the n-type output transistor part 11. Also, output lines 8 (three lines in FIG. 4) that transmit the output signal OUT are placed between the power lines 6 and the power lines 7 to extend in the X direction. The power lines 6 and 7 and the output lines 8 are placed with the minimum spacing among them under constraints in the manufacturing processes.

In the BMO layer, lines extending in the Y direction are formed. Power lines 21 supplying VSS are provided under the n-type output transistor part 11 and overlap the power lines 7 in the BM1 layer in planar view. The power lines 21 and the power lines 7 are mutually connected through vias. Power lines 22 supplying VDDIO are provided under the p-type output transistor part 12 and overlap the power lines 6 in the BM1 layer in planar view. The power lines 22 and the power lines 6 are mutually connected through vias. Output lines 23 that transmit the output signal OUT are provided under the n-type output transistor part 11 and the p-type output transistor part 12, and overlap the output lines 8 in the BM1 layer in planar view. The output lines 23 and the output lines 8 are mutually connected through vias.

In the n-type output transistor part 11, the active region 31 forming the channel, source, and drain of the transistor N1 is formed in the lower-transistor makeup portion. In FIG. 5, three active regions 31 are formed, and each active region 31 includes six nanosheets 32. In the active regions 31, portions that are to be the source of the transistor N1 are connected to the VSS-supply power lines 21 through vias, and portions that are to be the drain of the transistor N1 are connected to the output lines 23 through vias.

In the p-type output transistor part 12, the active region 35 forming the channel, source, and drain of the transistor P1 is formed in the lower-transistor makeup portion. In FIG. 5, three active regions 35 are formed, and each active region 35 includes six nanosheets 36. In the active regions 35, portions that are to be the source of the transistor P1 are connected to the VDDIO-supply power lines 22 through vias, and portions that are to be the drain of the transistor P1 are connected to the output lines 23 through vias.

In the n-type output transistor part 11, local interconnects 41 extending in the Y direction are placed on the upper faces of the portions that are to be the source of the transistor N1 in the active regions 31. In the p-type output transistor part 12, local interconnects 42 extending in the Y direction are placed on the upper faces of the portions that are to be the source of the transistor P1 in the active regions 35. Also, from the n-type output transistor part 11 over to the p-type output transistor part 12, local interconnects 43 extending in the Y direction are placed on the upper faces of the portions that are to be the drain of the transistor N1 in the active regions 31 and the portions that are to be the drain of the transistor P1 in the active regions 35.

In the n-type output transistor part 11, the active region 51 forming the channel, source, and drain of the transistor N1 is formed in the upper-transistor makeup portion. In FIG. 6, three active regions 51 are formed, and each active region 51 includes six nanosheets 52.

In the p-type output transistor part 12, the active region 55 forming the channel, source, and drain of the transistor P1 is formed in the upper-transistor makeup portion. In FIG. 6, three active regions 55 are formed, and each active region 55 includes six nanosheets 56.

In the n-type output transistor part 11, gate interconnects 61 extending in the Y direction and the Z direction are formed. The gate interconnects 61 surround the peripheries of the nanosheets 32 in the active regions 31 and the nanosheets 52 in the active regions 51 in the Y direction and the Z direction through gate insulating films (not shown). The gate interconnects 61 correspond to the gate of the transistor N1.

In the p-type output transistor part 12, gate interconnects 65 extending in the Y direction and the Z direction are formed. The gate interconnects 65 surround the peripheries of the nanosheets 36 in the active regions 35 and the nanosheets 56 in the active regions 55 in the Y direction and the Z direction through gate insulating films (not shown). The gate interconnects 65 correspond to the gate of the transistor P1.

In the n-type output transistor part 11, local interconnects 44 extending in the Y direction are placed on the upper faces of the portions that are to be the source of the transistor N1 in the active regions 51. In the p-type output transistor part 12, local interconnects 45 extending in the Y direction are placed on the upper faces of the portions that are to be the source of the transistor P1 in the active regions 55. Also, from the n-type output transistor part 11 over to the p-type output transistor part 12, local interconnects 46 extending in the Y direction are placed on the upper faces of the portions that are to be the drain of the transistor N1 in the active regions 51 and the portions that are to be the drain of the transistor P1 in the active regions 55.

The local interconnects 41 and the local interconnects 44 overlapping each other in planar view are mutually connected through vias. That is, the portions that are to be the source of the transistor N1 in the active regions 31 and 51 are mutually connected. The local interconnects 42 and the local interconnects 45 overlapping each other in planar view are mutually connected through vias. That is, the portions that are to be the source of the transistor P1 in the active regions 35 and 55 are mutually connected. The local interconnects 43 and the local interconnects 46 overlapping each other in planar view are mutually connected through vias. That is, the portions that are to be the drain of the transistor N1 in the active regions 31 and 51 and the portions that are to be the drain of the transistor P1 in the active regions 35 and 55 are mutually connected.

In an MO interconnect layer that is a metal interconnect layer located above the local interconnect layer, metal interconnects 71 and 72 extending in the X direction are formed. The metal interconnects 71 (two in FIG. 6) are connected to the gate interconnects 61 through vias. The metal interconnects 72 (two in FIG. 6) are connected to the gate interconnects 65 through vias. The metal interconnects 71 transmit the output control signal INN, and the metal interconnects 72 transmit the output control signal INP.

Having the configuration described above, only the VDDIO-supply power lines 6 and 22, the VSS-supply power lines 7 and 21, and the output lines 8 and 23 that transmit the output signal OUT are laid as the interconnects formed in the backside portion of the semiconductor chip. Also, in the BM1 layer, the power lines 6 and 7 and the output lines 8 are laid to the maximum extent. Therefore, the output circuit can pass a large current.

Also, the active regions 31 and 35 of the lower transistor are connected to the backside lines only through vias. Since this can reduce the resistance value, the output circuit can pass a large current.

Moreover, in the n-type output transistor part 11, both the upper transistor and the lower transistor are n-type transistors. In the p-type output transistor part 12, both the upper transistor and the lower transistor are p-type transistors. It is therefore possible to increase the current flowing from the output circuit.

In other words, in this embodiment, the n-type output transistor part 11 constituting the transistor N1 connected between the power supply VSS and the output terminal OUT includes the active regions 31 and 51. The active regions 31 and 51 overlap each other in planar view, constituting the transistor N1. The power lines 21 and the output lines 23 are placed in the interconnect layer on the back side of the transistor N1 so as to overlap the active regions 31 and 51 in planar view. The power lines 21 are connected to the lower faces of the portions that are to be the source of the transistor N1 in the active regions 31 through vias, and the output lines 23 are connected to the lower faces of the portions that are to be the drain of the transistor N1 in the active regions 31 through vias.

Also, the p-type output transistor part 12 constituting the transistor P1 connected between the power supply VDDIO and the output terminal OUT includes the active regions 35 and 55. The active regions 35 and 55 overlap each other in planar view, constituting the transistor P1. The power lines 22 and the output lines 23 are placed in the interconnect layer on the back side of the transistor P1 so as to overlap the active regions 35 and 55 in planar view.

The power lines 22 are connected to the lower faces of the portions that are to be the source of the transistor P1 in the active regions 35 through vias, and the output lines 23 are connected to the lower faces of the portions that are to be the drain of the transistor P1 in the active regions 35 through vias.

With the configuration described above, it is possible to implement the output circuit capable of passing a large current to the output terminal without the need to widen the layout area.

While the power lines 6, 7, 21, and 22 and the output lines 8 and 23 are formed in the interconnect layers provided in the backside portion of the semiconductor chip, the configuration is not limited to this. In the present disclosure, it is only required to form the power lines and the output lines on the back side of the transistors. The back side of the transistors as used herein refers to the side, with respect to the transistors, opposite to the side on which the local interconnects and the metal interconnects connected to the transistors are stacked one upon another.

The power lines 6, 7, 21, and 22 and the output lines 8 and 23 may be formed in a plurality of interconnect layers.

Moreover, an interconnect layer may be formed further below the BM1 layer to form backside lines. In this case, the directions in which the lines extend may be changed alternately, such as that lines extend in the Y direction in a BM2 layer and extend in the X direction in a BM3 layer, for example.

### (Another Configuration Example)

The power lines and the output lines formed on the back side of the transistors described above may be formed using a semiconductor chip other than the semiconductor chip in which the transistors are formed.

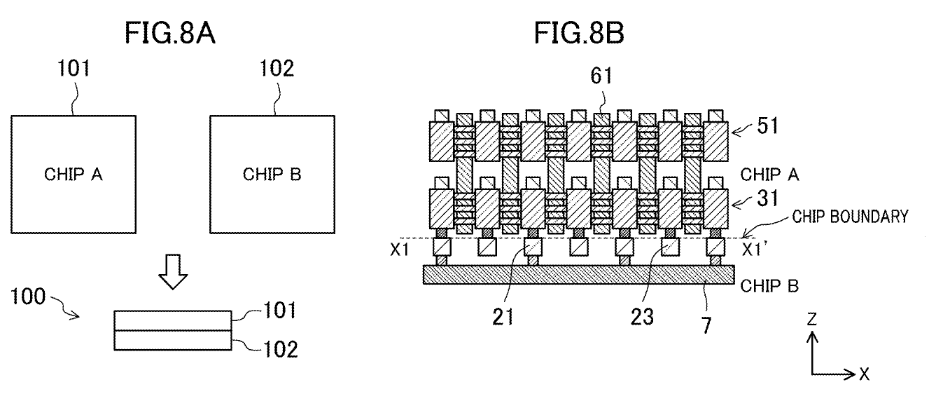

FIG. 8A shows another configuration example of the semiconductor integrated circuit device according to the embodiment. A semiconductor integrated circuit device 100 shown in FIG. 8A is constituted by a first semiconductor chip 101 (chip A) and a second semiconductor chip 102 (chip B) stacked one upon the other. In the chip A, the above-described IO cells, standard cells, and the like are placed. In the chip B, the power lines and the output lines are formed in interconnect layers provided on the surface. The chip B is bonded to the back of the chip A using bumps and the like.

FIG. 8B shows a cross section in this configuration example taken along line X1-X1' of the output circuit shown in FIGS. 4 to 6. As shown in FIG. 8B, the power lines and the output lines formed in the BMO layer and the BM1 layer in the above embodiment are formed in the interconnect layers provided on the surface of the chip B.

With this configuration example, also, effects similar to those in the output circuit described above can be obtained. Note that, in this configuration example, also, the power lines and the output lines may be formed in a plurality of interconnect layers. Note also that, in this configuration example, power lines in a layer further below the BM1 layer are also formed in the chip B.

### (Alteration)

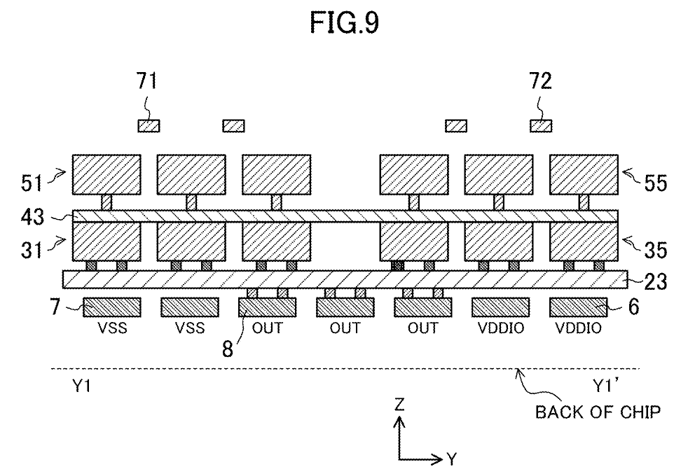

FIG. 9 shows a configuration of a cross section taken along line Y1-Yl' of an output circuit according to an alteration. In the configuration of FIG. 9, the bottoms of the active regions 51 and 55 of the upper transistor are connected to the local interconnects 43 formed on the upper faces of the active regions 31 and 35 of the lower transistor through vias. Similarly, although illustration is omitted, the local interconnects 41 formed on the upper faces of the active regions 31 of the lower transistor are connected to the bottoms of the active regions 51 of the upper transistor through vias. The local interconnects 42 formed on the upper faces of the active regions 35 of the lower transistor are connected to the bottoms of the active regions 55 of the upper transistor through vias. No local interconnects are formed on the upper faces of the active regions 51 and 55 of the upper transistor. Note however that local interconnects may be formed on the upper faces of the active regions 51 and 55.

With the configuration described above, since the resistance value on the routes to the upper transistor can be reduced, the output circuit can pass a still larger current.

Furthermore, it is also possible to form no local interconnects on the upper faces of the active regions 31 and 35 of the lower transistor, either, and connect the upper faces of the active regions 31 and the lower faces of the active regions 51 through vias, and connect the upper faces of the active regions 35 and the lower faces of the active region 55 through vias.

### (Second Embodiment)

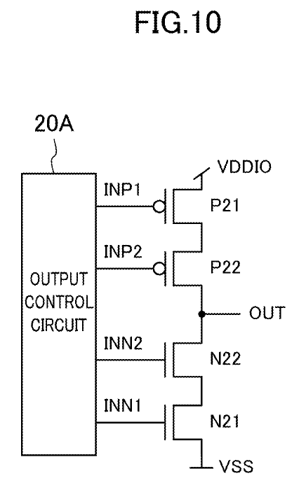

FIG. 10 is a circuit diagram of an output circuit in the second embodiment. In this embodiment, the IO cell 10A shown in FIG. 2 includes the output circuit shown in FIG. 10. In the output circuit of FIG. 10, p-type transistors P21 and P22 are serially provided between the power supply VDDIO and the output terminal OUT, and n-type transistors N21 and N22 are serially provided between the power supply VSS and the output terminal OUT. An output control circuit 20A outputs output control signals INP1, INP2, INN 1, and INN2. The transistor P21 receives the output control signal INP1 at its gate, and the transistor P22 receives the output control signal INP2 at its gate. The transistor N21 receives the output control signal INN1 at its gate, and the transistor N22 receives the output control signal INN2 at its gate. The output signal OUT is supplied to an external connection pad. When the output control signals INP1, INP2, INN 1, and INN2 are low in level, the output signal OUT is high (VDDIO), and when the output control signals INP1, INP2, INN1, and INN2 are high, the output signal OUT is low (VSS). Note that one of the output control signals INP1 and INP2 may be a fixed potential (VSS) and one of the output control signals INN1 and INP2 may be a fixed potential (VDDIO).

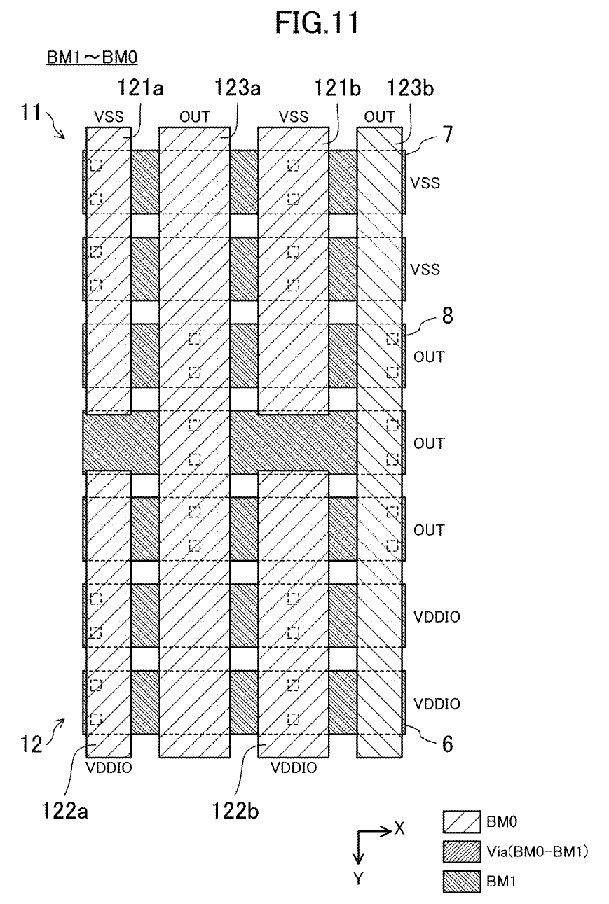

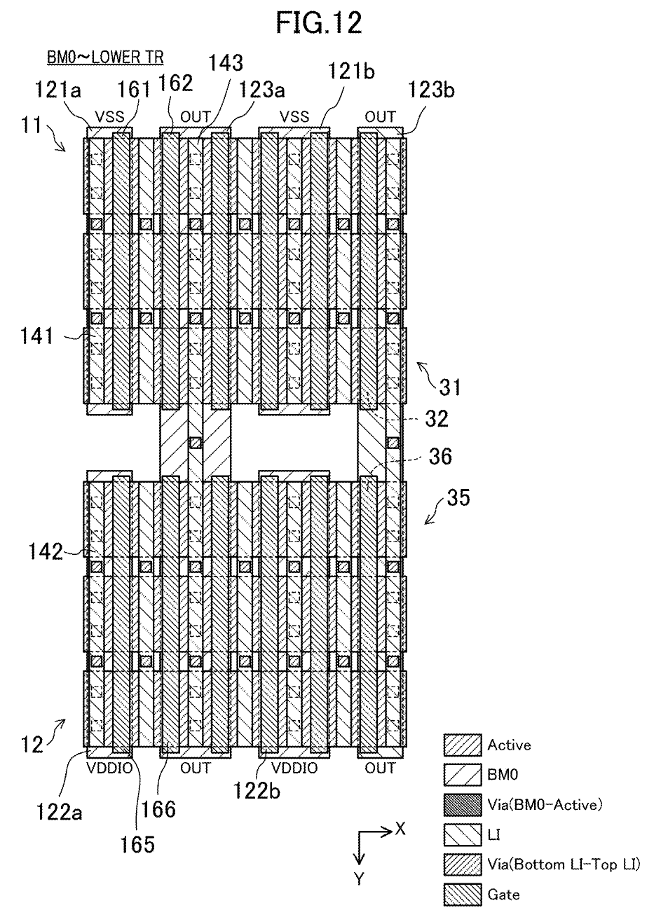

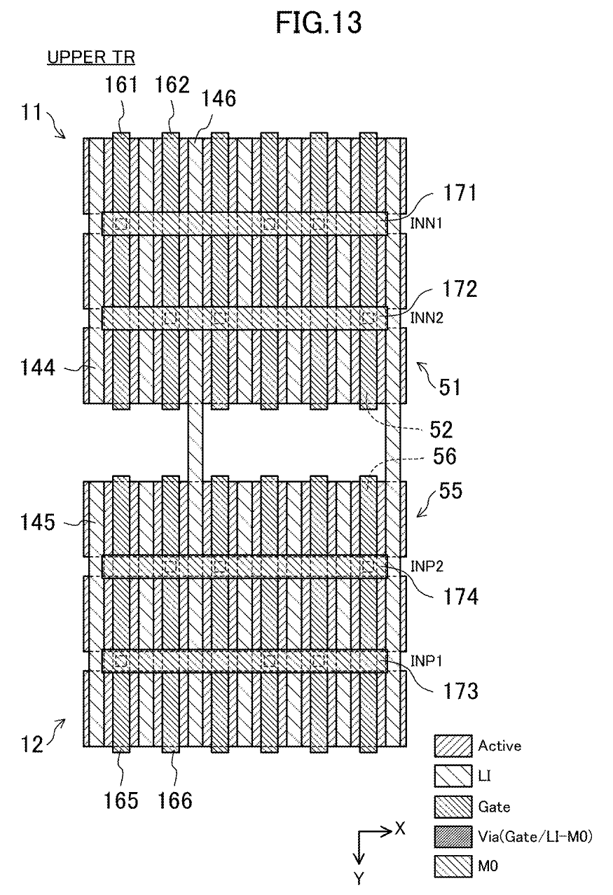

FIGS. 11, 12, and 13 are plan views showing a layout of the output transistor parts in the IO cell 10A shown in FIG. 2 in this embodiment. FIGS. 11, 12, and 13 show the layout layer by layer: FIG. 11 shows a configuration of backside lines, FIG. 12 shows a configuration of a lower transistor, and FIG. 13 shows a configuration of an upper transistor. Note that, since the cross-sectional structures in this embodiment are similar to those in the first embodiment and can be easily understood from the first embodiment, illustration thereof is omitted here.

In FIGS. 11 to 13, the upper part of the figure corresponds to the n-type output transistor part 11 constituting the transistors N21 and N22, and the lower part of the figure corresponds to the p-type output transistor part 12 constituting the transistors P21 and P22. Nanosheet FETs are formed in the n-type output transistor part 11 and the p-type output transistor part 12.

In the layout in the FIGS. 11 to 13, in comparison with the layout in the FIGS. 4 to 6, since the transistors are in two-stage serial connection, each two nanosheets are formed, and two gate interconnects are placed, between the power supply VSS or VDDIO and the output terminal OUT. The basic structure is however similar to that in the first embodiment, and therefore detailed description will be omitted here for configurations easily understandable from the description in the first embodiment.

In the BMO layer, VSS-supply power lines 121a and 121b are provided under the n- type output transistor part 11 and overlap the power lines 7 in the BM1 layer in planar view. The power lines 121a and 121b and the power lines 7 are mutually connected through vias. VDDIO-supply power lines 122a and 122b are provided under the p-type output transistor part 12 and overlap the power lines 6 in the BM1 layer in planar view. The power lines 122a and 122b and the power lines 6 are mutually connected through vias. Output lines 123a and 123b are provided under the n-type output transistor part 11 and the p-type output transistor part 12, and overlap the output lines 8 in the BM1 layer in planar view. The output lines 123a and 123b and the output lines 8 are connected through vias.

In the n-type output transistor part 11, active regions 31 forming the channels, sources, and drains of the transistors N21 and N22 are formed in the lower-transistor makeup portion. In the active regions 31, portions that are to be the source of the transistor N21 are connected to the VSS-supply power lines 121a and 121b through vias. In the active regions 31, portions that are to be the drain of the transistor N22 are connected to the output lines 123a and 123b through vias.

In the p-type output transistor part 12, active regions 35 forming the channels, sources, and drains of the transistors P21 and P22 are formed in the lower-transistor makeup portion. In the active regions 35, portions that are to be the source of the transistor P21 are connected to the VDDIO-supply power lines 122a and 122b through vias. In the active regions 35, portions that are to be the drain of the transistor P22 are connected to the output lines 123a and 123b through vias.

In the n-type output transistor part 11, local interconnects 141 extending in the Y direction are placed on the upper faces of the portions that are to be the source of the transistor N21 and on the upper faces of the portions that are to be the drain of the transistor N21 and also the source of the transistor N22 in the active regions 31. In the p-type output transistor part 12, local interconnects 142 extending in the Y direction are placed on the upper faces of the portions that are to be the source of the transistor P21 and on the upper faces of the portions that are to be the drain of the transistor P21 and also the source of the transistor P22 in the active regions 35. Also, from the n-type output transistor part 11 over to the p-type output transistor part 12, local interconnects 143 extending in the Y direction are placed on the upper faces of the portions that are to be the drain of the transistor N22 in the active regions 31 and the portions that are to be the drain of the transistor P22 in the active regions 35.

In the n-type output transistor part 11, active regions 51 forming the channels, sources, and drains of the transistors N21 and N22 are formed in the upper-transistor makeup portion.

In the p-type output transistor part 12, active regions 55 forming the channels, sources, and drains of the transistors P21 and P22 are formed in the upper-transistor makeup portion.

In the n-type output transistor part 11, gate interconnects 161 and 162 extending in the Y direction and the Z direction are formed. The gate interconnects 161 and 162 surround the peripheries of the nanosheets 32 in the active regions 31 and the nanosheets 52 in the active regions 51 in the Y direction and the Z direction through gate insulating films (not shown). The gate interconnects 161 correspond to the gate of the transistor N21, and the gate interconnects 162 correspond to the gate of the transistor N22.

In the p-type output transistor part 12, gate interconnects 165 and 166 extending in the Y direction and the Z direction are formed. The gate interconnects 165 and 166 surround the peripheries of the nanosheets 36 in the active regions 35 and the nanosheets 56 in the active regions 55 in the Y direction and the Z direction through gate insulating films (not shown). The gate interconnects 165 correspond to the gate of the transistor P21, and the gate interconnects 166 correspond to the gate of the transistor P22.

In the n-type output transistor part 11, local interconnects 144 extending in the Y direction are placed on the upper faces of the portions that are to be the source of the transistor N21 and on the upper faces of the portions that are to be the drain of the transistor N21 and also the source of the transistor N22 in the active regions 51. In the p-type output transistor part 12, local interconnects 145 extending in the Y direction are placed on the upper faces of the portions that are to be the source of the transistor P21 and on the upper faces of the portions that are to be the drain of the transistor P21 and also the source of the transistor P22 in the active regions 55. Also, from the n-type output transistor part 11 over to the p-type output transistor part 12, local interconnects 146 extending in the Y direction are placed on the upper faces of the portions that are to be the drain of the transistor N22 in the active regions 51 and the portions that are to be the drain of the transistor P22 in the active regions 55.

The local interconnects 141 and the local interconnects 144 overlapping each other in planar view are mutually connected through vias. That is, the portions that are to be the source of the transistor N21 in the active regions 31 and 51 are mutually connected. Also, the portions that are to be the drain of the transistor N21 and also the source of the transistor N22 in the active regions 31 and 51 are mutually connected. The local interconnects 142 and the local interconnects 145 overlapping each other in planar view are mutually connected through vias. That is, the portions that are to be the source of the transistor P21 in the active regions 35 and 55 are mutually connected. Also, the portions that are to be the drain of the transistor P21 and also the source of the transistor P22 in the active regions 35 and 55 are mutually connected.

The local interconnects 143 and the local interconnects 146 overlapping each other in planar view are mutually connected through vias. That is, the portions that are to be the drain of the transistor N22 in the active regions 31 and 51 and the portions that are to be the drain of the transistor P22 in the active regions 35 and 55 are mutually connected.

In an MO interconnect layer that is a metal interconnect layer located above the local interconnect layer, metal interconnects 171, 172, 173, and 174 extending in the X direction are formed. The metal interconnect 171 is connected to the gate interconnects 161 through vias.

The metal interconnect 172 is connected to the gate interconnects 162 through vias. The metal interconnect 173 is connected to the gate interconnects 165 through vias. The metal interconnect 174 is connected to the gate interconnects 166 through vias. The metal interconnect 171 transmits the output control signal INN1, and the metal interconnect 172 transmits the output control signal INN2. The metal interconnect 173 transmits the output control signal INP1, and the metal interconnect 174 transmits the output control signal INP2.

Having the configuration described above, only the VDDIO-supply power lines 6, 122a, and 122b, the VSS-supply power lines 7, 121a, 121b, and the output lines 8, 123a, and 123b that transmit the output signal OUT are laid as the interconnects formed in the backside portion of the semiconductor chip. Also, in the BM1 layer, the power lines 6 and 7 and the output lines 8 are laid to the maximum extent. Therefore, the output circuit can pass a large current.

Also, the active regions 31 and 35 of the lower transistor are connected to the backside power lines only through vias. Since this can reduce the resistance value, the output circuit can pass a large current.

Moreover, in the n-type output transistor part 11, both the upper transistor and the lower transistor are n-type transistors. In the p-type output transistor part 12, both the upper transistor and the lower transistor are p-type transistors. It is therefore possible to increase the current flowing from the output circuit.

In other words, in this embodiment, the n-type output transistor part 11 having the transistors N21 and N22 connected in series between the power supply VSS and the output terminal OUT includes the active regions 31 and 51. The active regions 31 and 51 overlap each other in planar view, constituting the transistors N21 and N22. The power lines 121a and 121b and the output lines 123a and 123b are placed in the interconnect layer on the back side of the transistors N21 and N22 so as to overlap the active regions 31 and 51 in planar view. The power lines 121a and 121b are connected to the lower faces of the portions that are to be the source of the transistor N21 in the active regions 31 through vias, and the output lines 123a and 123b are connected to the lower faces of the portions that are to be the drain of the transistor N22 in the active regions 31 through vias.

Also, the p-type output transistor part 12 having the transistors P21 and P22 connected in series between the power supply VDDIO and the output terminal OUT includes the active regions 35 and 55. The active regions 35 and 55 overlap each other in planar view, constituting the transistors P21 and P22. The power lines 122a and 122b and the output lines 123a and 123b are placed in the interconnect layer on the back side of the transistors P21 and P22 so as to overlap the active regions 35 and 55 in planar view. The power lines 122a and 122b are connected to the lower faces of the portions that are to be the source of the transistor P21 in the active regions 35 through vias, and the output lines 123a and 123b are connected to the lower faces of the portions that are to be the drain of the transistor P22 in the active regions 35 through vias.

With the configuration described above, it is possible to implement the output circuit capable of passing a large current to the output terminal without the need to widen the layout area.

As in the first embodiment, the power lines 6, 7, 121a, 121b, 122a, and 122b and the output lines 8, 123a, and 123b may be formed in a plurality of interconnect layers.

Moreover, an interconnect layer may be formed further below the BM1 layer to form backside lines. In this case, the directions in which the lines extend may be changed alternately, such as that lines extend in the Y direction in a BM2 layer and extend in the X direction in a BM3 layer, for example.

Also, the other configuration example and the alteration in the first embodiment are also applicable to this embodiment. That is, the power lines and the output lines formed on the back side of the transistors may be formed using a semiconductor chip other than the semiconductor chip in which the transistors are formed. Also, the active regions of the upper transistor and the active regions of the lower transistor may be electrically connected to each other as in the manner described in the alteration of the first embodiment.

In this embodiment, the upper transistor and the lower transistor are the same in conductivity type. That is, in the n-type output transistor part 11, both the upper and lower active regions are of the n-type, and in the p-type output transistor part 12, both the upper and lower active regions are of the p-type. Instead of this, the upper and lower active regions may have different conductivity types from each other in the entire output transistor parts. For example, the upper active regions may have n-type and the lower active regions may have p- type. Alternatively, the upper active regions may have p-type and the lower active regions may have n-type. This simplifies the manufacturing processes of the entire output circuit, and therefore facilitates the manufacture of the semiconductor integrated circuit device.

While it has been described that nanosheet FETs are formed in the transistor parts in the above embodiments, the transistors formed in the transistor parts are not limited to nanosheet FETs. For example, the transistors formed in the transistor parts may be fin FETs.

According to the present disclosure, an output circuit capable of passing a large current to an output terminal can be implemented without the need to widen the layout area. The present disclosure is therefore useful for improvement in the performance of a semiconductor chip, for example.

What is claimed is:

1. An output circuit for outputting a signal from a semiconductor integrated circuit, comprising: a first output transistor part including a first transistor of a first conductivity type connected between a first power supply supplying a first power supply voltage and an output terminal; a first power line supplying the first power supply voltage; and an output line connected to the output terminal, wherein the first output transistor part includes a first active region forming a channel, source, and drain of the first transistor, and a second active region forming a channel, source, and drain of the first
transistor, formed in a layer above the first active region, and overlapping the first active region in planar view, the first power line is placed on a back side of the first transistor so as to overlap the first and second active regions in planar view, and connected to a lower face of a portion that is to be the source of the first transistor in the first active region through a via, and the output line is placed in a same interconnect layer as the first power line so as to overlap the first and second active regions in planar view, and connected to a lower face of a portion that is to be the drain of the first transistor in the first active region through a via.

2. The output circuit ofclaim 1, wherein the portion that is to be the source of the first transistor in the first active region and
a portion that is to be the source of the first transistor in the second active region are electrically connected to each other, and the portion that is to be the drain of the first transistor in the first active region and a portion that is to be the drain of the first transistor in the second active region are electrically
connected to each other.

3. The output circuit ofclaim 2, further comprising: a first local interconnect provided on an upper face of the portion that is to be the source of the first transistor in the first active region; a second local interconnect provided on an upper face of the portion that is to be the drain of the first transistor in the first active region; a third local interconnect provided on an upper face of the portion that is to be the source of the first transistor in the second active region; and a fourth local interconnect provided on an upper face of the portion that is to be the
drain of the first transistor in the second active region,
wherein the first local interconnect and the third local interconnect are mutually connected through a via, and the second local interconnect and the fourth local interconnect are mutually connected through a via.

4. The output circuit ofclaim 2, further comprising: a first local interconnect provided on an upper face of the portion that is to be the source of the first transistor in the first active region; and a second local interconnect provided on an upper face of the portion that is to be the
drain of the first transistor in the first active region,
wherein the first local interconnect is connected to a lower face of the portion that is to be the source of the first transistor in the second active region through a via, and the second local interconnect is connected to a lower face of the portion that is to be the drain of the first
transistor in the second active region through a via.

5. The output circuit of claim 1, further comprising: a second output transistor part including a second transistor of a second conductivity type connected between a second power supply supplying a second power supply voltage and
the output terminal; and a second power line supplying the second power supply voltage,
wherein the second output transistor part includes a third active region forming a channel, source, and drain of the second
transistor, and a fourth active region forming a channel, source, and drain of the second transistor, formed in a layer above the third active region, and overlapping the third active region in planar view, the second power line is placed in a same interconnect layer as the first power line so
as to overlap the third and fourth active regions in planar view, and connected to a lower face of a portion that is to be the source of the second transistor in the third active region through a via, and the output line is placed so as to overlap the third and fourth active regions in planar view, and connected to a lower face of a portion that is to be the drain of the second transistor
in the third active region through a via.

6. The output circuit of claim 1, wherein the first power line and the output line are formed in an interconnect layer provided in a first semiconductor chip in which the first and second active regions are formed.

7. The output circuit ofclaim 1, wherein the first power line and the output line are formed in an interconnect layer provided in a second semiconductor chip bonded to a back of a first semiconductor chip in which the first and second active regions are formed.

8. An output circuit for outputting a signal from a semiconductor integrated circuit, comprising: a first output transistor part including first and second transistors of a first conductivity type connected serially between a first power supply supplying a first power
supply voltage and an output terminal; a first power line supplying the first power supply voltage; and an output line connected to the output terminal,
wherein the first output transistor part includes a first active region, and a second active region formed in a layer above the first active region and overlapping the first active region in planar view, at least one of the first and second active regions forms channels, sources, and drains of the first and second transistors, the first power line is placed on a back side of the first and second transistors so as to
overlap the first and second active regions in planar view, and connected to a lower face of a portion that is to be the source of the first transistor in the first active region through a via, and the output line is placed in a same interconnect layer as the first power line so as to overlap the first and second active regions in planar view, and connected to a lower face of a
portion that is to be the drain of the second transistor in the first active region through a via.

9. The output circuit of claim 8, wherein both the first and second active regions form the channels, sources, and drains of the first and second transistors.

10. The output circuit of claim 9, wherein the portion that is to be the source of the first transistor in the first active region and a portion that is to be the source of the first transistor in the second active region are electrically connected to each other, and the portion that is to be the drain of the second transistor in the first active region and a portion that is to be the drain of the second transistor in the second active region are electrically connected to each other.

11. The output circuit of claim 10, further comprising: a first local interconnect provided on an upper face of the portion that is to be the source of the first transistor in the first active region; a second local interconnect provided on an upper face of the portion that is to be the drain of the second transistor in the first active region; a third local interconnect provided on an upper face of the portion that is to be the
source of the first transistor in the second active region; and
a fourth local interconnect provided on an upper face of the portion that is to be the drain of the second transistor in the second active region,
wherein the first local interconnect and the third local interconnect are mutually connected
through a via, and the second local interconnect and the fourth local interconnect are mutually connected through a via.

12. The output circuit ofclaim 10, further comprising: a first local interconnect provided on an upper face of the portion that is to be the
source of the first transistor in the first active region; and a second local interconnect provided on an upper face of the portion that is to be the drain of the second transistor in the first active region,
wherein the first local interconnect is connected to a lower face of the portion that is to be the
source of the first transistor in the second active region through a via, and the second local interconnect is connected to a lower face of the portion that is to be the drain of the second transistor in the second active region through a via.

13. The output circuit ofclaim 8, further comprising: a second output transistor part including third and fourth transistors of a second conductivity type connected between a second power supply supplying a second power supply voltage and the output terminal; and a second power line supplying the second power supply voltage,
wherein the second output transistor part includes
a third active region, and
a fourth active region formed in a layer above the third active region, and overlapping the third active region in planar view,
at least one of the third and fourth active regions forms channels, sources, and drains
of the third and fourth transistors ,the second power line is placed in a same interconnect layer as the first power line so as to overlap the third and fourth active regions in planar view, and connected to a lower face of a portion that is to be the source of the third transistor in the third active region through a via, and the output line is placed in the same interconnect layer as the first power line so as to overlap the third and fourth active regions in planar view, and connected to a lower face of a portion that is to be the drain of the fourth transistor in the third active region through a via.

14. The output circuit ofclaim 8, wherein the first power line and the output line are formed in an interconnect layer provided in a first semiconductor chip in which the first and second active regions are formed.

15. The output circuit ofclaim 8, wherein the first power line and the output line are formed in an interconnect layer provided
in a second semiconductor chip bonded to a back of a first semiconductor chip in which the first and second active regions are formed.
